(19) United States
(12) Patent Application Publication
(10) Pub. No.: US 2012/0118504 A1
(43) Pub. Date: May 17, 2012

(54) PROCESSING APPARATUS AND METHOD FOR OPERATING SAME

(75) Inventors: Masamichi Nomura, Yamanashi (JP); Kenjiro Koizumi, Yamanashi (JP); Shigeru Kasai, Yamanashi (JP); Sumi Tanaka, Yamanashi (JP)

(73) Assignee: TOKYO ELECTRON LIMITED, TOKYO (JP)

(21) Appl. No.: 13/386,572

(22) PCT Filed: Jul. 21, 2010
(86) PCT No.: PCT/JP10/62243

§ 371 Date: Jan. 23, 2012

(30) Foreign Application Priority Data
Jul. 22, 2009 (JP) 2009-171558
Dec. 2, 2009 (JP) 2009-274987
Jun. 25, 2010 (JP) 2010-144572

(51) Int. Cl. B44C 1/22; C23C 16/458; C23C 16/52; B25B 11/00; B24C 3/00

(52) U.S. Cl. 156/345.28; 269/8; 451/75; 118/663

(57) ABSTRACT

A processing apparatus for performing a process on an object includes a chamber; a rotary floater for supporting the object on its upper end side; XY rotating attraction bodies provided in the rotary floater at an interval circumferentially; a floating attraction body provided in the rotary floater to extend circumferentially; a floating electromagnet group for floating the rotary floater while adjusting an inclination of the rotary floater by applying a vertically upward acting magnetic attraction to the floating attraction body; an XY rotating electromagnet group for rotating the rotary floater while adjusting a horizontal position of the rotary floater by applying a magnetic attraction force to the XY rotating attraction bodies; a gas supply for supplying a gas into the chamber; a mechanism for performing a process on the object; and an apparatus control unit for controlling an entire operation of the apparatus.

### FIELD OF THE INVENTION

The present invention relates to a processing apparatus for processing a target object to be processed, e.g., a semiconductor wafer or the like, and a method for operating same.

### BACKGROUND OF THE INVENTION

Generally, various heat treatments such as a film forming process, an annealing process, an oxidation/diffusion process, a sputtering process, an etching process and the like are repeatedly performed on a semiconductor wafer a predetermined number of times in order to manufacture a semiconductor integrated circuit. For example, in the film forming process, the factors for improving, e.g., uniformity in a film quality, a film thickness or the like on the semiconductor wafer include uniformity in distribution or flow of a reactant gas, uniformity in a wafer temperature, uniformity in a plasma and the like. In order to obtain processing uniformity in the wafer surface, it is required to rotate the wafer. A wafer rotating mechanism in a conventional processing apparatus includes a disc-shaped member for supporting a wafer; and a driving mechanism for rotating the disc-shaped member by using a frictional force generated through contact between the driving mechanism and the disc-shaped member.

Since, however, friction between objects causes to generate particles, it is inevitable that particles are generated from contact/friction portions in the wafer rotating mechanism of the conventional processing apparatus. Further, misalignment caused by sliding occurs between the disc-shaped member for supporting the wafer and a rotation unit of the driving mechanism for the disc-shaped member, so that an operation for returning to a reference position is required each time, causing a throughput deterioration.

For that reason, U.S. Pat. No. 6,157,106 discloses a configuration in which a rotor for supporting a wafer is rotated while being magnetically floated so that particles are not generated in a processing space. Particularly, in the technique disclosed in U.S. Pat. No. 6,157,106, the rotor is a constituent element of a rotor system floated by a magnetic force. Moreover, a magnetic field is generated by a stator assembly including a floating permanent magnet and a control electromagnet.

Further, Japanese Patent Application Publication No. 2008-305863 suggested by the present inventors discloses a technique designed to rotate a rotating floater for supporting a wafer by applying a magnetic force by a rotating electromagnet of a step motor while floating the rotary floater by a floating electromagnet; and to rotate the rotary floater while maintaining a center of rotation without misalignment in a horizontal plane by applying a horizontal magnetic force by a positioning electromagnet.

In the technique described in U.S. Pat. No. 6,157,106, the rotor is floated by a magnetic force applied thereto in a horizontal direction and, thus, the direction of the magnetic force does not coincide with the vertical direction of gravity applied to the rotor, so that vector directions of such acting forces are dispersed. As a result, it is complicated and difficult to control the magnetic floating.

In the technique described in Japanese Patent Application Publication No. 2008-305863, the rotating electromagnet and the positioning electromagnet are provided, so that the attractive forces thereof act to each other as external factors, thereby causing instability. For example, the attractive force generated by the rotating electromagnet of the step motor acts as an external factor that affects the positioning of the rotating floater in the horizontal plane. Therefore, the positioning electromagnet is affected, and this results in unstable positioning.

### SUMMARY OF THE INVENTION

The present invention has been developed to effectively solve the above-described drawbacks. The present invention provides a processing apparatus and a method for operating the same, the processing apparatus being capable of suppressing generation of unnecessary external factors by controlling a rotation torque and a diametrically (X and Y direction) acting force on the rotary floater by a same electromagnet, thereby realizing particle free environment while obtaining in-plane processing uniformity and simplifying structures and control processes.

In accordance with an aspect of the present invention, there is provided a processing apparatus for performing a process on a target object to be processed. The apparatus includes an evacuable processing chamber; a rotary floater disposed within the processing chamber to support the target object on an upper end side thereof, the rotary floater being made of a non-magnetic material; a plurality of XY rotating attraction bodies provided in the rotary floater at an interval in the circumferential direction thereof, the XY rotating attraction bodies being made of a magnetic material; a ring-like floating attraction body provided in the rotary floater to extend in the circumferential direction thereof, the floating attraction body being made of a magnetic material; a floating electromagnet group provided outside the processing chamber to float the rotary floater while adjusting an inclination of the rotary floater by applying a vertically upward acting magnetic attraction to the floating attraction body; an XY rotating electromagnet group provided outside the processing chamber to rotate the rotary floater while adjusting a horizontal position of the floating rotary floater by applying a magnetic attraction to the XY rotating attraction bodies; a gas supply unit for supplying a required gas into the processing chamber; a processing mechanism for performing a process on the target object; and an apparatus control unit for controlling an entire operation of the processing apparatus.

In accordance with the present invention, in the processing apparatus for performing a process on the wafer W as a target object to be processed, the rotation torque and the diametrically acting force (outward force) can be generated simultaneously by applying a magnetic attraction from the XY rotating electromagnet group 18 to the XY rotating attraction bodies 80 provided at the rotary floater 14 in a state where the rotary floater 14 is floated by the floating electromagnet group 16. Accordingly, it is possible to suppress unnecessary external factors from being generated by controlling the diametrically (X and Y directions) acting force and the rotation torque on the rotary floater 14 by the same electromagnet. As a result, the particle free environment can be realized while obtaining the in-plane processing uniformity, and the structures and the control processes can be simplified.

The processing apparatus may further include a vertical position sensor unit for detecting vertical position information of the rotary floater; and a floating control unit for supplying a control current to the floating electromagnet group to control a magnetic attraction based on an output of the vertical position sensor unit.

The processing apparatus may further include a horizontal position sensor unit for detecting horizontal position information of the rotary floater; an encoder unit for detecting a rotation angle of the rotary floater; and an XY rotating control unit for controlling a rotation torque and a diametrical force on the rotary floater by supplying a control current for controlling a magnetic attraction of the XY rotating electromagnet group based on an output of the horizontal position sensor unit and an output of the encoder unit.

The rotary floater may be provided with a home position adjustment portion having a measurement surface having an angle with respect to a rotation direction of the rotary floater, and a home detection sensor unit for detecting the home position adjustment portion may be provided at the processing chamber.

The home position adjustment portion may have a pair of the measurement surfaces forming an angle, and a straight line extending in a diametrical direction of the rotating float body and passing through the contact point between the pair of measurement surfaces may be a bisector of the angle formed by the measurement surfaces.

The pair of measurement surfaces may be formed as a V-shaped cut-out portion at a position corresponding to the horizontal position sensor unit, and the pair of the measurement surfaces forming the cut-out portion may be provided in plural at an interval along the circumferential direction of the rotary floater.

The horizontal position sensor unit may also serve as the home detection sensor unit, and the XY rotating control unit may be configured to stop the rotary floater at a home position by detecting a depth of the cut-out portion in the case of stopping the rotary floater.

The XY rotating control unit may be configured to stop the rotary floater at a home position by detecting a position of the measurement surface in the diametrical direction of the rotary floater based on an output of the home detection sensor unit in the case of stopping the rotary floater.

The rotary floater may be provided with an origin mark indicating the origin, and the processing chamber may be provided with an origin sensor unit for detecting the origin mark.

The floating electromagnet group may include plural pairs of floating electromagnetic units, each pair being formed of two electromagnets having rear surfaces connected to each other by a yoke, and the plural pairs of floating electromagnetic units may be arranged at an interval along the circumferential direction of the processing chamber.

The XY rotating electromagnet group may include plural pairs of XY rotating electromagnetic units, each pair being formed of two electromagnets having rear surfaces connected to each other by a yoke. The plural pairs of XY rotating electromagnetic units may be arranged at an interval along the circumferential direction of the processing chamber.

The two electromagnets of each pair of the XY rotating electromagnetic units may be arranged at different levels in a height direction of the processing chamber, and plural pairs of magnetic poles made of a ferromagnetic material may be provided in the processing chamber while being spaced from each other at an interval along the circumferential direction of the processing chamber, each pair of the magnetic poles being arranged to correspond to the two electromagnets of each pair of the electromagnetic units.

The floating electromagnet group may be provided at a bottom portion of the processing chamber.

The floating electromagnet group may be provided at a ceiling portion of the processing chamber.

A diffusely reflecting surface for diffusedly reflecting a measurement light may be formed on a surface of the rotary floater which faces the vertical position sensor unit.

A diffusely reflecting surface for diffusedly reflecting a measurement light may be formed on the surface of the rotary floater which faces the horizontal position sensor unit.

The diffusely reflecting surface may be formed by a blasting process.

A size number of a blast grain in the blasting process may range from #100 (grain size number 100) to #300 (grain size number 300).

The blast grain may be made of a material selected from a group consisting of glass, ceramic, and dry ice.

An average surface roughness of a blast target surface before the blasting process may be set to be smaller than a desired average surface roughness after the blasting process.

An alumite film may be formed on the diffusedly reflective surface after the blasting process.

The diffusely reflecting surface may be formed by an etching process.

The diffusely reflecting surface may be formed by a coating process.

In accordance with another aspect of the present invention, there is provided a method for operating the processing apparatus. The method includes floating the rotary floater while controlling an inclination thereof by applying a magnetic attraction to the floating attraction body by the floating electromagnet group; and rotating the rotary floater while controlling a horizontal position thereof by applying a magnetic attraction to the XY rotating attraction bodies by the XY rotating electromagnet group.

The method may further include controlling the floating control unit to control the floating electromagnet group and the XY rotating control unit to control the electromagnet group during processing of the target object based on variation data on variations in characteristics. The variation data on variations in characteristics may be obtained by previously rotating the rotary floater by the floating control unit and the XY rotating control unit.

The method may further include controlling the floating control unit to control the floating electromagnet group and the XY rotating control unit to control the XY rotating electromagnet group during processing of the target object based on distortion data on distortion of the rotary floater. The distortion data on distortion of the rotary floater may be obtained by previously rotating the rotary floater.

The XY rotating control unit may stop the rotary floater at a home position based on an output of an encoder unit for detecting a rotation angle of the rotary floater and an output of the home detection sensor unit for detecting a home position adjustment portion having measurement surfaces formed at the rotary floater, in the case of stopping the rotary floater.

The home position adjustment portion may be formed by arranging a plurality of V-shaped cut-out portions along a circumferential direction of the rotary floater, each of the cut-out portions being formed as a pair of measurement surfaces, and the home detection sensor unit may also serve as a horizontal position sensor unit for detecting a horizontal position of the rotary floater.

The method may further include supplying, when the rotary floater starts to rotate at an uncertain position, a control current for rotating the rotary floater in one direction to the XY rotating electromagnetic units while assuming that the rotary floater is stopped at a preset home position; supplying, when the rotary floater stops its rotation, a control current for magnetizing the XY rotating electromagnetic units by misaligning the XY rotating electromagnetic units of the XY rotating electromagnet group by an angle, to the XY rotating electromagnet group; supplying, when the rotary floater is rotated at a decreasing speed, a control current for rotating the rotary floater in a reverse direction, to the XY rotating electromagnet group; and resetting the encoder unit by detecting an origin position when an origin mark of the rotary floater passes through an origin sensor unit.

### BRIEF DESCRIPTION OF THE DRAWINGS

FIG. 1 is a full vertical cross sectional view showing a processing apparatus in accordance with a first embodiment of the present invention.

FIG. 2 is a schematic side cross sectional view showing attachment portions between XY rotating attraction bodies and an XY rotating electromagnet group in the processing apparatus shown in FIG. 1.

FIG. 3 is a schematic side view for explaining a positional relationship between an XY rotating electromagnet group and a rotary floater.

FIG. 4 is a fragmentary enlarged cross sectional view for explaining an interrelationship between an XY rotating electromagnetic unit and an XY rotating attraction body.

FIG. 5 is an enlarged top view showing a pair of magnetic poles provided to correspond to XY rotating electromagnets.

FIG. 6A is an enlarged view showing an example of a cut-out portion of a home position adjustment portion.

FIG. 6B is an enlarged view showing another example of the cut-out portion of the home position adjustment portion.

FIG. 7 is a graph showing relationship between a rotation torque and a magnetic attraction force (attraction force) acting on an XY rotating attraction body.

FIG. 8 is a graph showing a relationship between a depth and a rotation angle in a V-shaped cut-out portion provided at a rotary floater.

FIG. 9 is a vertical cross sectional schematic view showing an example of a magnetic field passing through an XY rotating electromagnetic unit and an XY rotating attraction body.

FIG. 10A is a schematic view showing changes in the magnetic field passing through the XY rotating electromagnet and the XY rotating attraction body while being rotated.

FIG. 10B is a schematic view showing changes in the magnetic field passing through the XY rotating electromagnet and the XY rotating attraction body while being rotated.

FIG. 10C is a schematic view showing changes in the magnetic field passing through the XY rotating electromagnet and the XY rotating attraction body while being rotated.

FIG. 11 explains components of a magnetic attraction force applied to the XY rotating attraction body.

FIG. 12A is a schematic view for explaining an example of a structure and an operation of a sensor unit.

FIG. 12B is a graph for explaining an operation of the sensor unit.

FIG. 13 is a flowchart showing a process for controlling a floating state of a rotary floater.

FIG. 14 is a flowchart showing a process for controlling a rotation and a horizontal position of a rotary floater.

FIG. 15 is a graph showing a relationship between test pieces A to F and respective amounts of received light in the case of examining diffusedly reflective surfaces.

FIG. 16 is a full vertical cross sectional view showing a processing apparatus in accordance with a second embodiment of the present invention.

FIG. 17 is a schematic perspective view showing a floating electromagnet group provided at a ceiling portion of a processing chamber.

FIG. 18 is a schematic perspective view showing an example of a rotary floater.

FIG. 19A is an enlarged cross sectional view showing an example of a home position adjustment portion.

FIG. 19B is an enlarged cross sectional view showing another example of the home position adjustment portion.

### DETAILED DESCRIPTION OF THE EMBODIMENTS

Hereinafter, embodiments of a processing apparatus and a method for operating the same will be described in detail with reference to the accompanying drawings.

### First Embodiment

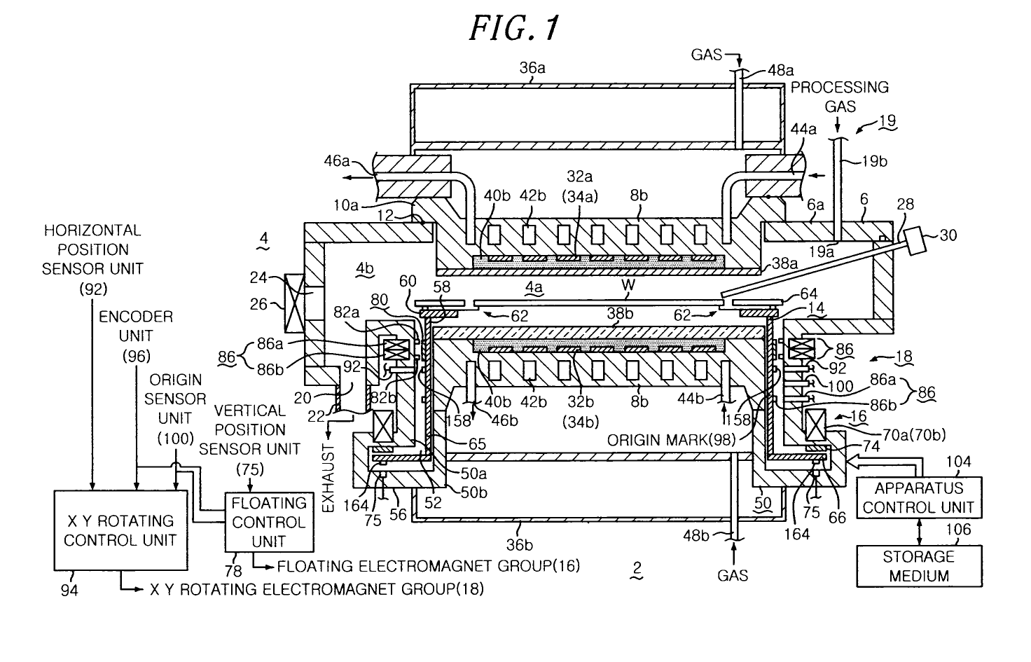

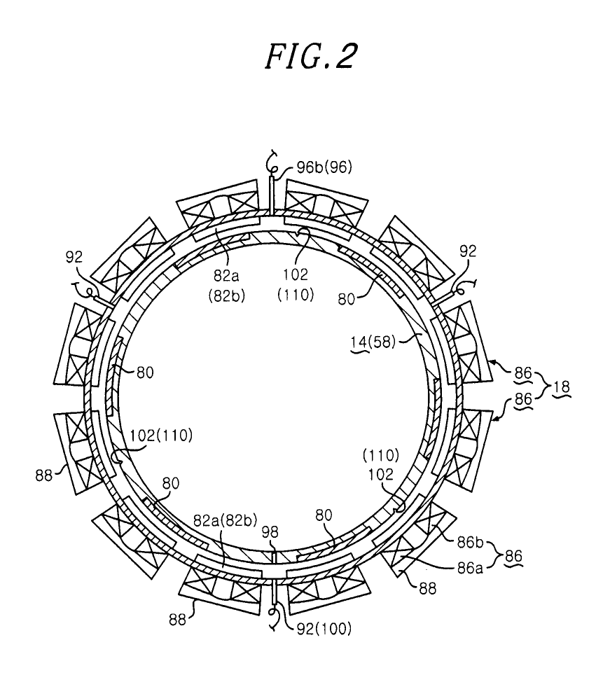

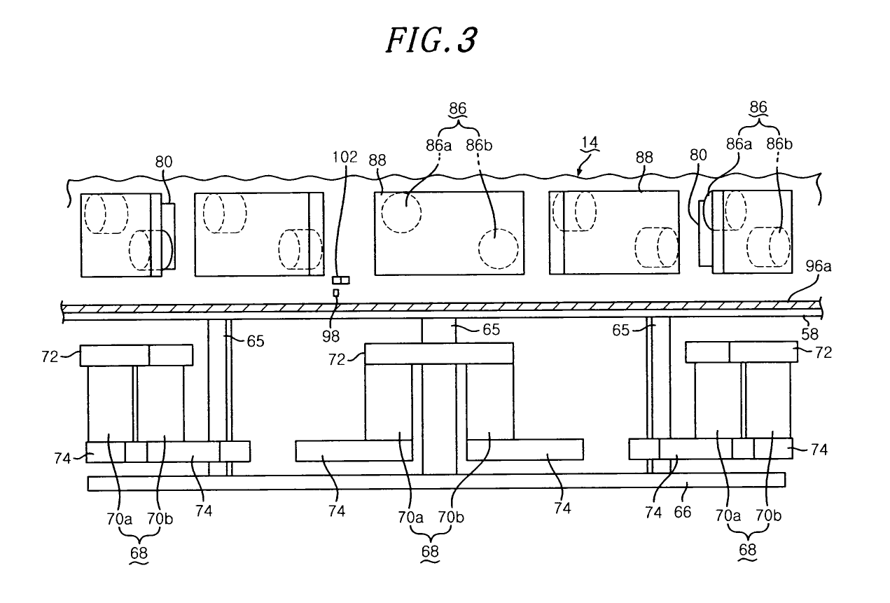

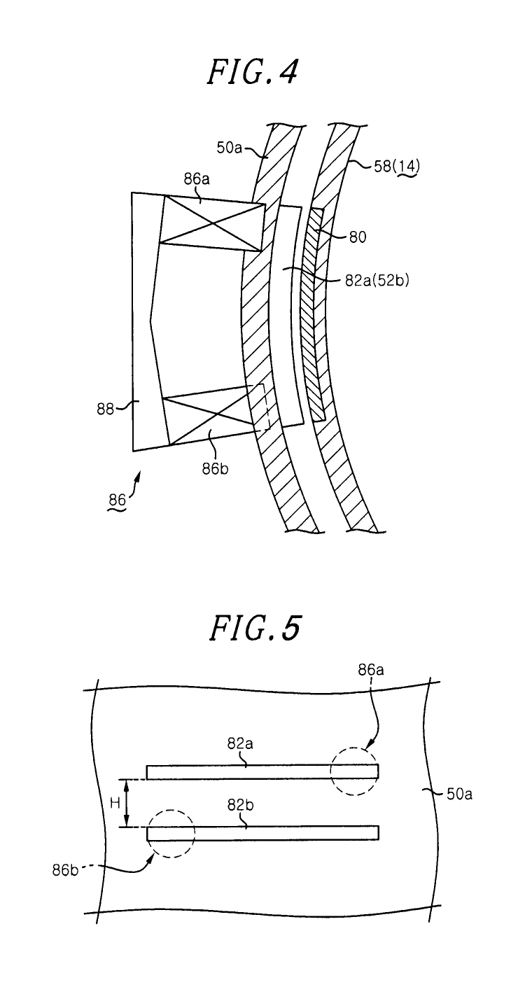

FIG. 1 is a full vertical cross sectional view showing a processing apparatus in accordance with a first embodiment of the present invention. FIG. 2 is a schematic side cross sectional view showing attachment portions between XY rotating attraction bodies and an XY rotating electromagnet group of the processing apparatus of FIG. 1. FIG. 3 is a schematic side view for explaining a positional relationship between an XY rotating electromagnet group and a rotary floater. FIG. 4 is a fragmentary enlarged cross sectional view for explaining an interrelationship between an XY rotating electromagnetic unit and an XY rotating attraction body.

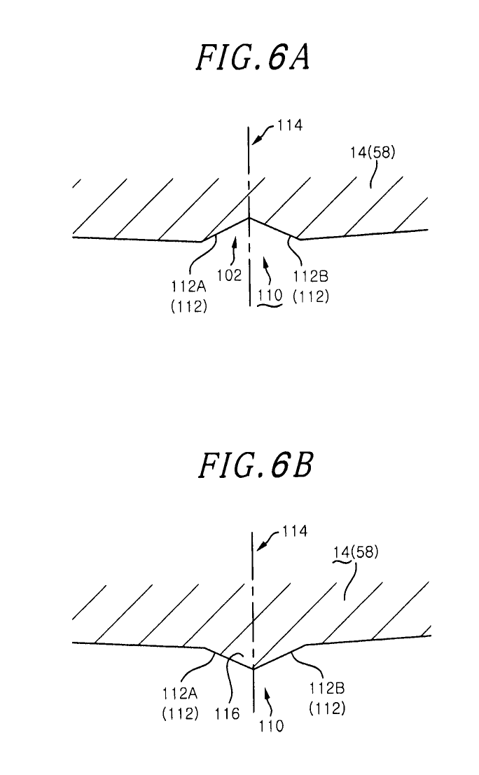

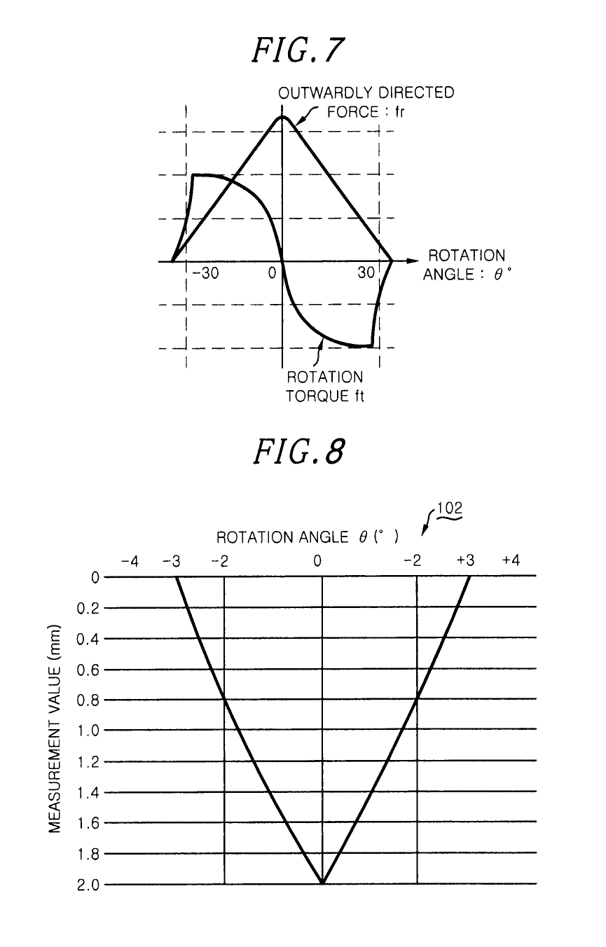

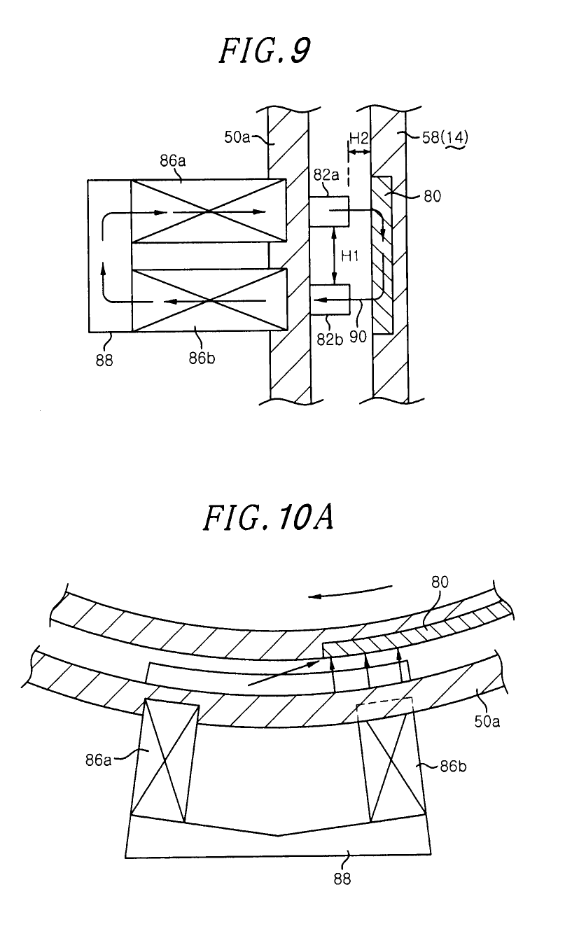

FIG. 5 is an enlarged top view showing a pair of magnetic poles provided to correspond to XY rotating electromagnets. FIG. 6A is an enlarged view showing an example of a cut-out portion of a home position adjustment portion. FIG. 6B is an enlarged view showing another example of the cut-out portion of the home position adjustment portion. FIG. 7 is a graph showing a relationship between a rotation torque and a magnetic attraction force (attraction force) acting on an XY rotating attraction body. FIG. 8 is a graph showing a relationship between a depth and a rotation angle in a V-shaped cut-out portion provided at a rotary floater. FIG. 9 is a vertical cross sectional schematic view showing an example of magnetic field passing through an XY rotating electromagnetic unit and an XY rotating attraction body.

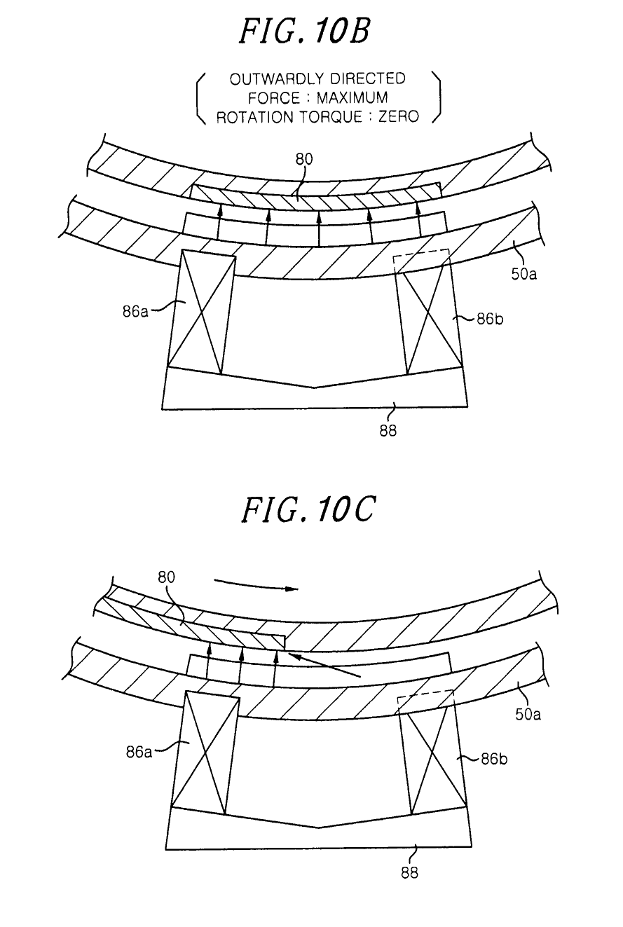

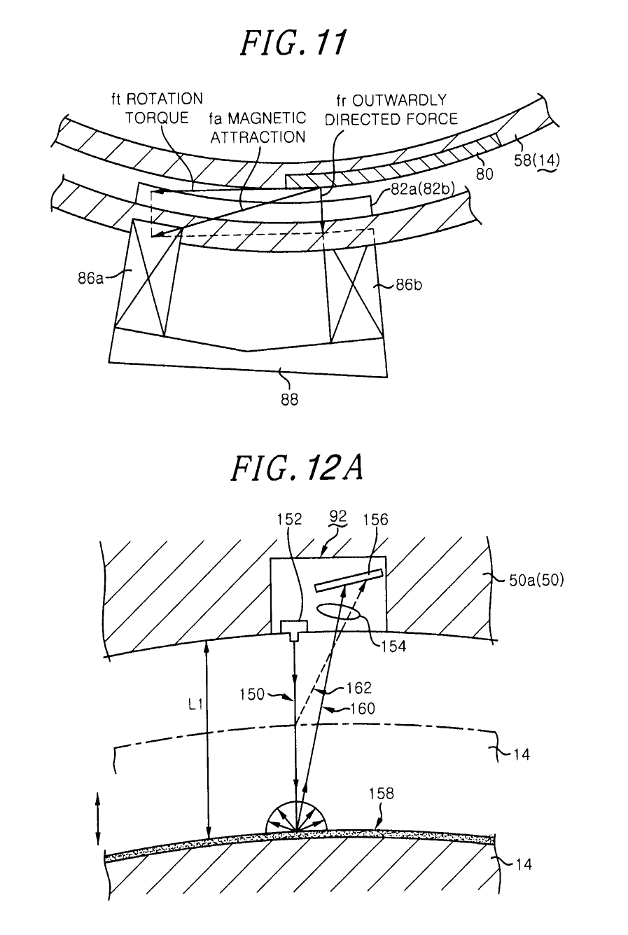

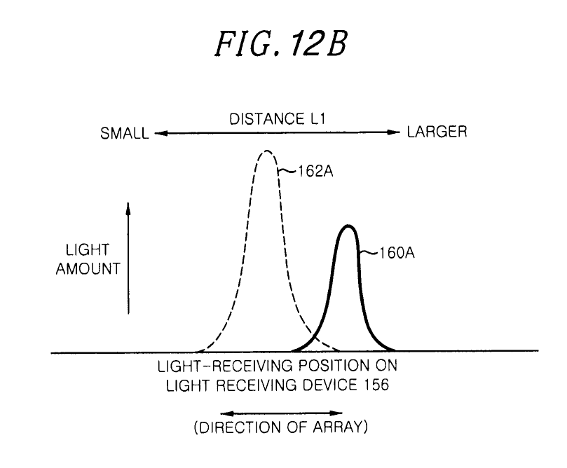

FIG. 10A is a schematic view showing changes in the magnetic field passing through the XY rotating electromagnet and the XY rotating attraction body while being rotated. FIG. 10B is a schematic view showing changes in the magnetic field passing through the XY rotating electromagnet and the XY rotating attraction body while being rotated. FIG. 10C is a schematic view showing changes in the magnetic field passing through the XY rotating electromagnet and the XY rotating attraction body while being rotated. FIG. 11 explains components of a magnetic attraction force applied to the XY rotating attraction body. FIG. 12A is a schematic view for explaining an example of a structure and an operation of a sensor unit. FIG. 12B is a graph for explaining the operation of the sensor unit.

Here, a processing apparatus for performing a predetermined process, e.g., an annealing process, on a semiconductor wafer as a target object to be processed will be described as an example.

As shown in FIG. 1, a processing apparatus 2 includes an airtight processing space 4 into which a wafer W is loaded. The processing space 4 has a cylindrical annealing section 4a where the wafer W is disposed; and a doughnut-shaped gas diffusion section 4b arranged around the annealing section 4a. The gas diffusion section 4b has a height higher than that of the annealing section 4a, and the processing space 4 has a substantial H-shaped cross section. The gas diffusion section 4b of the processing space 4 is defined by a processing chamber 6. Circular openings corresponding to the annealing section 4a are respectively formed on a top wall and a bottom wall of the processing chamber 6, and cooling members 8a and 8b, each made of a high thermal conductive material such as copper or the like, are respectively inserted into these openings.

The cooling members 8a and 8b respectively have flange portions 10a (only the upper side is shown) closely adhered to a top wall 6a of the processing chamber 6 via sealing members 12. Further, the annealing processing portion 4a is defined by the cooling members 8a and 8b. In the processing space 4 there is provided a rotary floater 14 for horizontally supporting the wafer W in the annealing processing portion 4a. The position of the rotary floater 14 is controlled in the horizontal plane while being floated by a floating electromagnet group 16 and rotated by an XY rotating electromagnet group 18, which will be described later.

Moreover, a processing gas supply unit 19 for introducing a predetermined processing gas from a processing gas supply mechanism (not shown) is provided on the ceiling wall of the processing chamber 6. The processing gas supply unit 19 has a processing gas inlet port 19a, and a processing gas line 19b through which a processing gas is supplied is connected to the processing gas inlet port 19a. Further, a gas exhaust port 20 is provided on the bottom wall of the processing chamber 6, and a gas exhaust line 22 connected to a gas exhaust unit (not shown) is connected to the gas exhaust port 20.

Furthermore, a loading/unloading port 24 through which the wafer W is loaded to and unloaded from the processing chamber 6 is provided on a sidewall of the processing chamber 6, and can be opened and closed by a gate valve 26. In the processing space 4, there is provided a temperature sensor 28 for measuring a temperature of the wafer W. Besides, the temperature sensor 28 is connected to a measurement unit 30 provided outside the processing chamber 6, and a temperature detection signal is outputted from the measurement unit 30. Heating sources 32a and 32b serving as processing units are respectively provided on the inner surfaces of the cooling members 8a and 8b, so as to face the wafer W. Specifically, the heating sources 32a and 32b are formed of, e.g., light emitting diodes (hereinafter, referred to as “LED”) 34a and 34b, and configured to heat both sides of the wafer W by one or more LED arrays having a plurality of LEDs which are arranged in a planar shape.

Control boxes 36a and 36b for controlling power supply to the LEDs 34a and 34b are respectively provided above the cooling member 8a and below the cooling member 8b, and wirings extended from a power supply (not shown) are respectively connected to the control boxes 36a and 36b to control power supply to the LEDs 34a and 34b. Light-transmitting members 38a and 38b through which light emitted from the LEDs 34a and 34b of the heating sources is transmitted toward the wafer W are fixed by screws on the surfaces of the cooling members 8a and 8b which face the wafer W. The light-transmitting members 38a and 38b are made of a material, e.g., quartz, which effectively transmits light emitted from the LEDs 34 and 34b.

Moreover, transparent resins 40a and 40b are respectively filled in peripheral portions of the LEDs 34a and 34b. Silicon resin, epoxy resin or the like may be employed as the transparent resins 40a and 40b. The cooling members 8a and 8b are provided with coolant flow paths 42a and 42b for circulating therethrough a liquid coolant, e.g., fluorine-based inactive liquid (Fluorinert (trademark), Galden (trademark) or the like) capable of cooling the cooling members 8a and 8b to a temperature of 0° C. or less, e.g., about −50° C. Coolant supply lines 44a and 44b are respectively connected to the coolant flow paths 42a and 42b of the cooling members 8a and 8b. Further, coolant discharge lines 46a and 46b are respectively connected to the coolant flow paths 42a and 42b of the cooling members 8a and 8b. Therefore, the cooling members 8a and 8b can be cooled by circulating the coolant through the coolant flow paths 42a and 42b.

Further, dry gas is introduced into a space between the control box 36a and the cooling member 8a through a gas line 48a and into a space between the control box 36b and the cooling member 8b through a gas line 48b. The lower portion, i.e., the bottom portion of the processing chamber 6 is formed as a casing 50 for a rotary floater, which forms a part of the processing chamber 6. The casing 50, made of a non-magnetic material, e.g., aluminum, aluminum alloy or the like, is formed in a cylindrical shape having a so-called double pipe structure in which a ring-shaped accommodation space 52 for accommodating the rotary floater 14 therein is formed. An upper end of an outer wall 50a of the cylindrical casing 50 having the double pipe structure is connected to a bottom portion of a wall defining the gas diffusion section 4b, and an upper end of an inner wall 50b is connected to the lower cooling member 8b. Further, a lower end portion of the casing 50 having the double pipe structure is bent outward at a right angle, thereby forming a ring-shaped horizontal flange portion 56.

(Structure of Rotary Floater 14)

Hereinafter, the structure of the rotary floater 14 will be described. The rotary floater 14 is mainly made of a non-magnetic material, e.g., aluminum, aluminum alloy or the like. Specifically, the rotary floater 14 has a cylindrical rotary main body 58, and a circular plate ring-shaped supporting ring 60 is provided at an upper end portion of the rotary main body 58. Provided at an inner side of the supporting ring 60 are L-shaped supporting arms 62, each extending in a radially inward direction and having a leading end bent upward at a right angle.

Three supporting arms 62 (only two are shown in FIG. 1) spaced from each other at regular intervals are provided along the circumferential direction of the supporting ring 60 to support wafers W at leading end portions thereof by contacting with circumferential edges of backsides of the wafers W. The supporting arms 62 are made of, e.g., quartz or ceramic.

A uniform-heating ring 64 is provided above the supporting ring 60 at the same horizontal level as the wafer W to improve the temperature uniformity in the wafer surface. The uniform-heating ring 64 is made of, e.g., polysilicon.

A vertical length of the rotary main body 58 is set to a minimum length so that the weight of the rotary floater 14 can be minimized. Supports 65 (see FIG. 3) are provided below the rotary main body 58 to be extended downward therefrom, wherein the supports 65 are arranged to be spaced apart from each other at regular intervals along the circumferential direction thereof. In FIG. 3, an outer wall 50a of the casing 50 which forms a part of the processing chamber 6 is omitted. For example, eight supports 65 are provided, and a ring-shaped floating attraction body 66 which is made of a ferromagnetic material extends along the circumferential direction of the rotary floater 14 so as to connect with the lower end portions of the supports 65.

The attraction body 66 is formed of, e.g., an electromagnetic steel plate, in order to reduce an eddy current loss caused by rotation thereof. The attraction body 66 is accommodated in the horizontal flange portion 56 of the casing 50. Here, a space for allowing the rotary floater 14 to be moved vertically by at least about 1 cm in a floating state is secured in the space in the horizontal flange portion 56 in order to transfer the wafer W between the rotary floater 14 and a transfer arm (not shown) during loading and unloading of the wafer W.

Provided outside the horizontal flange portion 56 is the floating electromagnet group 16 for floating the rotary floater 14 by applying a vertically upward acting magnetic attraction to the floating attraction body 66. As shown in FIG. 3, the floating electromagnet group 16 includes a plurality of electromagnetic units 68. For example, in this embodiment, six floating electromagnetic units 68 are spaced apart from each other at regular intervals along the circumferential direction of the casing 50 forming a part of the bottom portion of the processing chamber 6. Each of the six floating electromagnetic units 68 has a pair of two floating electromagnets, so that a total of three pairs are disposed at an interval of about 120°.

Specifically, each of the floating electromagnetic units 68 includes two electromagnets 70a and 70b standing upward in parallel with each other, and the rear sides thereof are connected to each other by a yoke 72 made of a ferromagnetic material. Since the three pairs of the floating electromagnetic units 68 are arranged at the interval of about 120°, the inclination of the rotary floater 14 can be freely controlled, and the rotary floater 14 can be rotated by the XY rotating electromagnet group 18 and the like to be described later while maintaining the horizontal state thereof.

The attachment portions of the horizontal flange portion 56 to which the electromagnets 70a and 70b are attached are cut in a recess shape having a thin thickness of about 2 mm, to have a small magnetic resistance. Floating ferromagnetic members 74 are attached to inner portions of the horizontal flange portion 56, corresponding to the attached electromagnets 70a and 70b, with a gap of about 2 mm with respect to the floating electromagnetic unit 68. The floating ferromagnetic members 74 are provided one for each pair of the electromagnets 70a and 70b along the circumferential direction to act a magnetic attraction on the floating attraction body 66. Thus, the attracting magnetic force is increased.

Accordingly, a magnetic circuit is formed by the yoke 72, the two electromagnets 70a and 70b, the floating ferromagnetic members 74, and the floating attraction body 66. The magnetic attraction acting on the floating attraction body 66 makes the entire rotary floater 14 be floated (non-contact state). The horizontal flange portion 56 is provided with a vertical position sensor unit (Z-axis sensor) 75 for detecting vertical position information of the rotary floater 14. In this embodiment, a plurality of, e.g., three, sensor units 75 are arranged at an interval of, e.g., about 120°, along the circumferential direction of the horizontal flange portion 56. By inputting such a detected value to a floating control unit 78 including a computer or the like, the height or the inclination of the rotary floater 14 can be detected and controlled.

The rotary floater 14 is floated from the bottom portion by about 2 mm as a reference position. The rotary floater 14 can be rotated at the reference position, where the floating of the rotary floater 14 is maintained, and can be lifted from the reference position by about 10 mm when the wafer is received or transferred. In this embodiment, the magnetization of the floating electromagnet group 16 is controlled by PWM control (pulse width control).

A plurality of XY rotating attraction bodies 80 which characterizes the present invention is provided at the rotary main body 58 made of a non-magnetic material while being spaced from each other at regular intervals along the circumferential direction of the rotary floater 14. The attraction bodies 80 are made of a magnetic material.

Specifically, as shown in FIG. 2, each of the XY rotating attraction bodies 80 is formed of a rectangular plate disposed along the circumferential direction of the rotating main body 58. In this embodiment, six attraction bodies 80 are buried in the rotating main body 58 while being spaced from each other at regular intervals. The attraction bodies 80 may be made of either a hard magnetic material or a soft magnetic material. In this embodiment, it is made of a soft magnetic material, e.g., SS400.

The length (width) of each of the attraction bodies 80 in the rotational direction is set to be equal to the gap between the attraction bodies 80 adjacent to each other. The attraction bodies 80 are set to have a vertical length allowing them to face a pair of magnetic poles 82a and 82b to be described later. When the rotating main body 58 has a diameter of, e.g., about 600 mm, the attraction bodies 80 have vertical and horizontal dimensions of, e.g., about 50 mm×160 mm.

The XY rotating electromagnet group 18 is provided at an outer side of the outer wall 50a of the casing 50 so as to face the attraction bodies 80 in a floating state of the rotary floater 14. By acting a magnetic attraction on the attraction bodies 80, the floating rotary floater 14 can be rotated while the position of the rotary floater 14 is controlled in the horizontal direction (X and Y directions). Here, the X and Y directions are perpendicular to each other in the horizontal plane.

Specifically, as shown in FIG. 2, the electromagnet group 18 includes twelve XY rotating electromagnetic units 86. The electromagnetic units 86 are arranged at a regular interval along the circumferential direction of the casing 50. Each of the electromagnetic units 86 has two electromagnets 86a and 86b. The electromagnets 86a and 86b are installed at different heights. For example, one electromagnet 86a is installed at a higher position, and the other electromagnet 86b is installed at a position slightly lower than that of the electromagnet 86a. The rear sides of the electromagnets 86a and 86b are connected to each other by a yoke 88 made of a ferromagnetic material. The attachment portions of the outer wall 50a to which the electromagnets 86a and 86b are attached are cut in a recess shape to have a thin thickness of about 2 mm and a small magnetic resistance.

A pair of magnetic poles 82a and 82b is attached to an inner portion of the outer wall 50a with a gap of about 2 mm with respect to each of the electromagnetic units 86 (see FIGS. 4 and 5). The magnetic poles 82a and 82b are made of a ferromagnetic material, and attached along the circumferential direction of the casing 50 with a predetermined gap in a vertical direction.

Specifically, the upper magnetic pole 82a is attached so as to correspond to the upper electromagnet 86a, and the lower magnetic pole 82b is attached so as to correspond to the lower electromagnet 86b. The length of the magnetic poles 82a and 82b in the circumferential direction of the casing 50 is set to be equal to the length of the attraction bodies 80. Moreover, a distance H1 (see FIGS. 5 and 9) between the magnetic poles 82a and 82b is set to about 20 mm.

Accordingly, as shown in FIG. 9, a magnetic circuit is formed by one yoke 88, two electromagnets 86a and 86b, two magnetic poles 82a and 82b, and one attraction body 80. At this time, the electromagnets 86a and 86b are positioned in the vertical direction and the magnetic poles 82a and 82b are also positioned in the vertical direction, so that a vertical magnetic circuit is formed.

When a magnetic field 90 passes through this magnetic circuit, the rotary floater 14 can be rotated while the position of the rotary floater 14 is controlled in the X and the Y direction by the magnetic attraction acting on the attraction body 80, as described above. In this case, as will be described later, a rotation torque and a centripetal force (diametrical force) are applied to the rotary floater 14 by the magnetic attraction force. In this regard, a distance H2 (see FIGS. 5 and 9) between the magnetic poles 82a and 82b and the outer peripheral end of the rotary floater 14 is, e.g., about 4 mm.

A horizontal position sensor unit 92 for detecting a horizontal position information of the rotary floater 14 is provided at the outer wall 50a of the casing 50. Specifically, as shown in FIGS. 1 and 2, a plurality of, e.g., three, horizontal position sensor unit 92 is provided along the circumferential direction of the outer wall 50a at an interval of, e.g., about 120° as shown in FIG. 2. The position information obtained therefrom is inputted to an XY rotating control unit 94 including, e.g., a computer or the like. Hence, the electromagnet group 18 is controlled by the control unit 94. The number of the horizontal position sensor units 92 is not limited to three.

The casing 50 is provided with an encoder unit 96 (see FIG. 1) for detecting a rotation angle of the rotary floater 14. Specifically, the encoder unit 96 includes a periodically changing code pattern 96a formed along the circumferential direction of the rotary main body 58, and an encoder sensor unit 96b provided at the outer wall 50a to detect the changes in the code pattern 96a. The information obtained on the rotational angle can be supplied to the control unit 94 or the floating control unit 78. The encoder unit 96 may be an optical encoder or a magnetic encoder.

An origin mark 98 (see FIGS. 1 and 2) indicating the origin is formed at a single position of the rotating main body 58 of the rotary floater 14 in the circumferential direction. Further, an origin sensor unit 100 is provided on the outer wall 50a at a position corresponding to the origin mark 98 to detect the origin mark 98. The origin mark 98 may be, e.g., a thin and long slit of a small width. The origin mark 98 can be detected by, e.g., an optical origin sensor unit 100. The detection signal of the origin sensor unit 100 is inputted to the XY rotating control unit 94 or the floating control unit 78. Whenever the origin mark 98 is detected, the count value of the encoder unit 96 is reset. The rotation angle of the rotary floater 14 is measured by the encoder unit 96 based on this position where the origin mark 98 is detected.

When stopping the rotating wafer W (the rotary floater 14), it needs to be stopped at the same rotation position consistently. Meanwhile, the cost of the encoder unit 96 is increased as its accuracy (resolution) is increased. In view of preventing the increase in the apparatus cost, the encoder unit 96 having a moderate level of accuracy (resolution) is used. However, to compensate for insufficient resolution, home position adjustment portions 110 are provided at the rotary floater 14, and the positioning accuracy (resolution) in the rotation direction in the case of stopping the rotary floater 14 is maintained (compensated) at a high level by measuring predetermined positions in the home position adjustment portions 110.

Specifically, as shown in FIGS. 2 and 6A, a plurality of home position adjustment portions 110 (three spaced apart from each other at about 120° in this embodiment) is provided along the circumferential direction of the rotary floater 14. The home position adjustment portions 110 have measurement surfaces 112 having angles (diametrically tilted) with respect to the rotation direction of the rotary floater 14. Specifically, each of the home position adjustment portions 110 has a pair of measurement surfaces 112A and 112B (112) forming a predetermined angle, and a straight line 114 is disposed to pass through a connection node between the pair of measurement surfaces 112A and 112B and extend in the diametrical direction of the rotary floater 14 so as to serve as a bisector for dividing this angle equally.

In other words, each of the home position adjustment portions 110 has a cut-out portion 102 formed by sharply cutting the side surface of the rotary floater 14 in a V shape toward the central direction thereof, and the pair of measurement surfaces 112A and 112B (112) is formed at the cut-out portion 102. The measurement surfaces 112A and 112B are formed as reflective surfaces. The V-shaped cut-out portion 102 is formed on the outer peripheral surface of the rotary main body 58 to correspond to the horizontal level of the horizontal position sensor unit 92, and the horizontal position sensor unit 92 detects the depth of the V-shaped groove, i.e., the position of the rotary floater 14 in the diametrical direction. The horizontal position sensor unit 92 detects the home position adjustment portion 110 (the cut-out portion 102), thereby serving as the home detection sensor unit defined by the scope of the claims.

FIG. 8 is a graph showing a relationship between a depth and a rotation angle in the V-shaped cut-out portion 102 provided at the rotary floater. In FIG. 8, the width of the V-shaped opening of the cut-out portion 102 is represented as a rotation angle smaller than the resolution of the encoder unit 96. The rotation angle is set to an opening angle of about 6° ranging from −3° to +3°, and the depth (at the deepest portion) is set to about 2.0 mm. By setting a position corresponding to the predetermined depth in the V-shaped cut-out portion 102 to a home position, it is possible to stop the rotary floater 14 at the home position consistently with high accuracy.

In this embodiment, the V-shaped chamfered portion 102 serves as the home position adjustment portion 110. However, the present invention is not limited thereto, and a protrusion 116 having a protruded (mountain-shaped) cross section which is symmetrical to the V-shaped cut-out portion 102 may be formed as shown in FIG. 6B. At this time, the inclined surfaces of the protrusion 116 may serve as a pair of measurement surfaces 112A and 112B.

Hereinafter, sensors used in the vertical position sensor unit 75 and the horizontal position sensor unit 92 will be described. The sensor units 75 and 92 may employ any sensor capable of measuring a distance to an object subjected to a distance measurement. Here, as the vertical position sensor unit 75 or the horizontal position sensor unit 92, an illuminance sensor which is relatively inexpensive is used for measuring a distance to a target object based on the position of the peak value of the amount of reflective light from the target object. Although the horizontal position sensor unit 92 is representatively shown in FIGS. 12A and 12B, this same description is also applied to the vertical position sensor unit 75.

FIG. 12A shows a schematic configuration of the sensor unit 92, and FIG. 12B shows the amount of light in a light receiving device. As shown in FIG. 12A, the horizontal position sensor unit 92 includes a light emitting device 152 for emitting a measurement light 150, a condensing lens 154 for condensing a reflective light from the rotary floater 14 as the target object, and a light receiving device 156 for detecting the light condensed by the condensing lens 154.

The light emitting device 152 may be an LED device or a laser device. In the present embodiment, a laser device is used, for example. Therefore, a laser beam is emitted as a measurement light. Further, an image sensor array of CMOS (Complementary Metal-Oxide Semiconductor) having a specified length is used as an example of the light receiving device 156, so that the reflective light reflected at an angle slightly different from that of the measurement light 150 is focused and detected.

In this case, the peak position of the amount of light on the light receiving device 156 formed of the image sensor array is changed as shown in FIG. 12B in accordance with a distance L1 between the outer wall 50a of the casing 50 to which the sensor unit 92 is attached and the outer wall of the rotary floater 14. Hence, the distance L1 can be measured by obtaining this peak position. For example, a peak position 160A of the reflective light 160 from the rotary floater 14 at a certain specific position and a peak position 162A of a reflective light 162 from the rotary floater 14 at another position are different from each other on the array. Therefore, the distance L1 can be measured by using the peak positions.

In this case, in order to stably measure the distance to the rotary floater 14 as a target object for distance measurement, the surface, i.e., the reflective surface, of the rotary floater 14 which faces the sensor unit 92 is preferably formed as a diffusedly reflective surface 158, not as a mirror surface (see FIG. 1). Accordingly, as shown in FIG. 12A, the measurement light incident on the diffusedly reflective surface 158 is reflected while being diffused in all directions. The diffusedly reflective surface 158 is formed in a ring shape along the circumferential direction of the rotary floater 14 while maintaining a constant width. In this embodiment, a distance L1 is, e.g., about 40 mm, and the resolution of the distance in FIG. 12B is a few μm.

The diffusedly reflective surface 158 can be formed by performing any one of a blasting process, an etching process, a coating process and the like on the surface serving as the reflective surface. In the case of the blasting process, blast grains may be grains of glass, ceramic such as alumina or the like, dry ice or the like. Although the size number of the blast grain will be described later, it is preferably within the range from #100 (grain size 100) to #300 (grain size 300).

Further, an average surface roughness of the blast target surface before the blasting process is preferably set to be smaller than a desired average surface roughness after the blasting process. Hence, it is possible to reduce the adverse effect of tool marks attached to a blast target surface or the like during mechanical processing. After the blasting process is completed, it is also preferable to form an alumite film on the surface of the diffusedly reflective surface 158 to increase the mechanism strength of the diffusedly reflective surface 158.

As described above, the vertical position sensor unit 75 has the same configuration as that of the horizontal position sensor unit 92. Therefore, a diffusedly reflective surface 164 (see FIG. 1) having the same structure as the diffusedly reflective surface 158 is formed in a ring shape along the circumferential direction of the rotary floater 14 on the surface of the floating attraction body 66 which forms a part of the rotary floater 14 and faces the vertical position sensor unit 75.

In the processing apparatus 2 configured as described above, various controls of, e.g., a processing temperature, a processing pressure, a gas flow rate, start and stop of rotation of the rotary floater 14 and the like, are performed by an apparatus control unit 104 including, e.g., a computer. Computer-readable programs required for such control are stored in a storage medium 106. The storage medium 106 may be, e.g., a flexible disc, CD (Compact Disc), CD-ROM, a hard disc, a flash memory, DVD or the like. The floating control unit 78 or the XY rotating control unit 94 operates under the control of the apparatus control unit 104.

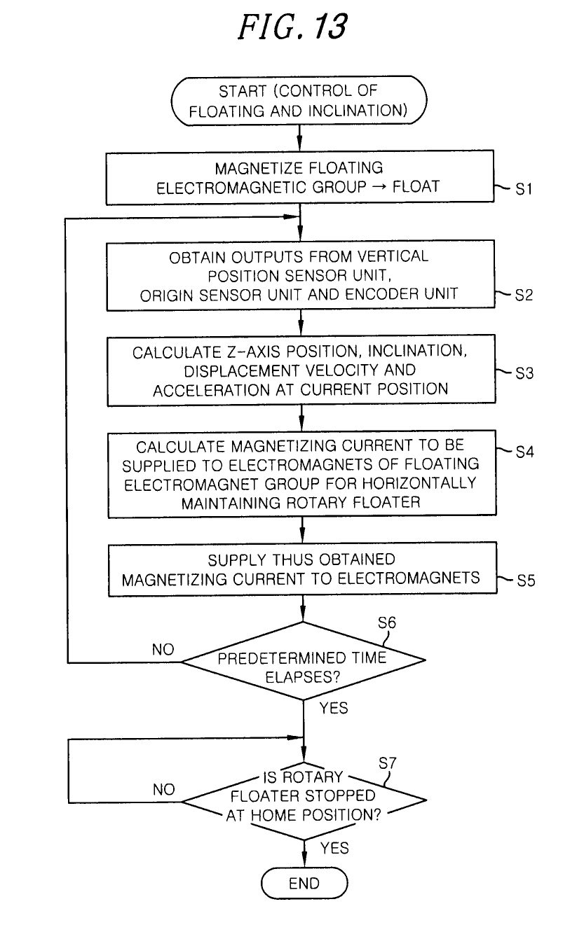

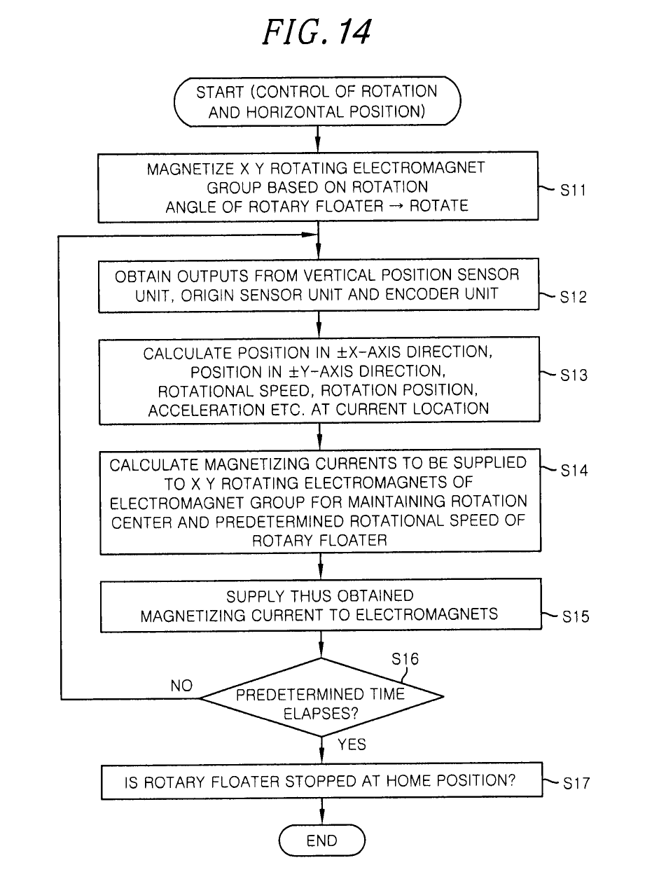

Hereinafter, the operation of the processing apparatus configured as described above will be explained with reference to the flowcharts of FIGS. 13 and 14. FIG. 13 is a flowchart showing a process for controlling a floating state of the rotary floater. FIG. 14 is a flowchart showing a process for controlling a rotation and a horizontal position of the rotary floater. The operations described in FIGS. 13 and 14 are performed simultaneously.

First of all, the gate valve 26 formed on the sidewall of the processing chamber 6 is opened, and an unprocessed wafer W held by a transfer arm (not shown) is loaded into the annealing section 4a in the processing chamber 6 through the loading/unloading port 24.

Next, the floating electromagnet group 16 is magnetized by the magnetizing current outputted from the floating control unit 78 and, thus, the rotary floater 14 is lifted to the uppermost level (S1). Accordingly, the wafer W is received by the supporting arms 62 provided at the upper end portion of the rotary floater 14. Then, the transfer arm is retreated, and the processing chamber 6 is sealed. Thereafter, the magnetizing current is reduced and, thus, the rotary floater 14 is lowered to the position for rotation and maintained in a floating state. During this period, the height position of the rotary floater 14 is constantly detected and feedback-controlled by the vertical position sensor unit 75 emitting the measurement light and receiving the reflective light thereof.

At this time, the rotary floater 14 is located at the home position in the rotation direction. This position is preset based on a count value of the encoder unit 96, and the rotation angle that is smaller than the resolution of the encoder unit 96 is determined with high accuracy by setting a specific depth (measurement value) of the V-shaped cut-out portion 102 shown in FIG. 8.

Next, an annealing processing gas is supplied from a gas supply unit 19 into the processing chamber 6 whose inner atmosphere is exhausted. Further, the LEDs 34a and 34b of the heating sources 32a and 32b serving as processing units are turned on, so that the wafer W is heated from both sides of the wafer and maintained at a predetermined temperature. At the same time, the magnetizing current flows from the XY rotating control unit 94 toward the XY rotating electromagnet group 18, thereby generating a magnetic field and rotating the rotary floater 14 (S11).

Hereinafter, floating control will be described. While the rotary floater 14 is rotated, detection signals outputted from the vertical position sensor unit 75, the origin sensor unit 100 and the encoder unit 96 are inputted to the floating control unit 78 (S2). The floating control unit 78 calculates a Z-axis position (height position), an inclination, a displacement velocity and an acceleration of the rotary floater 14 at the current position (S3). In accordance with the calculated results, magnetizing currents to be supplied to the electromagnets 70a and 70b of the floating electromagnet group 16 for horizontally maintaining the rotary floater 14 are calculated (S4). Then, the magnetizing currents calculated for the electromagnets 70a and 70b are supplied to the electromagnets 70a and 70b (S5).

Moreover, a value of the encoder unit 96 is reset whenever the origin mark is detected by the origin sensor unit 100, i.e., whenever rotation of 360° is completed. Accordingly, the rotary floater 14 can be constantly maintained at its horizontal state in a floating state regardless of the rotation angle. Until a predetermined processing time elapses, the processes of steps S2 to S5 are repeated (“NO” in S6).

When the predetermined processing time elapses (“YES” in S6), the rotary floater 14 is stopped at the home position (S7). The sequence of stopping the rotary floater 14 at the home position accurately will be described later.

Next, the control of the rotation and the horizontal position of the rotary floater 14 which are carried out simultaneously with the above operation will be described. As described above, when the rotary floater 14 is rotated by magnetizing the XY rotating electromagnet group 18 (S11), the detection signals outputted from the horizontal position sensor unit 92, the origin sensor unit 100 and the encoder unit 96 are inputted to the XY rotating control unit 94 (S12). The control unit 94 calculates a position in the ±X-axis direction, a position in the ±Y-axis direction, a rotational speed, a rotation position, acceleration and the like at the current location (S13).

In accordance with the results, the magnetizing currents to be supplied to the XY rotating electromagnets 86a and 86b of the electromagnet group 18 for maintaining the rotation center and the predetermined rotational speed of the rotary floater 14 are calculated (S14). The magnetizing currents obtained by the calculation are supplied to the electromagnets 86a and the 86b (S15). By the horizontal position sensor unit 92 emitting the measurement light and receiving the reflected light thereof, the horizontal position of the rotary floater 14 is constantly detected and feedback-controlled.

The magnetic attraction acting on the XY rotating attraction bodies 80 provided at the rotary floater 14 will be described later. As described above, since the rotation of the rotary floater 14 is feedback-controlled, the rotational speed (rotation torque) and the horizontal position of the rotary floater 14 are controlled with high accuracy. In addition, the rotary floater 14 is smoothly rotated without misalignment in the center of rotation while the floating state thereof is controlled and the horizontal position thereof is maintained.

Until the predetermined processing time elapses, the processes of steps S12 to S15 are repeated (“NO” in S16). After the predetermined processing time elapses (“YES” in S16), the rotary floater 14 is stopped at the home position (S17).

As described above, the resolution of the encoder unit 96 is not sufficiently good to stop the rotary floater 14 at the home position with high accuracy. Thus, if the rotary floater 14 is rotated to the vicinity of the home position based on the count value of the encoder unit 96, the depth of the V-shaped cut-out portion 102 is measured by the horizontal position sensor unit 92 (see FIG. 8). Then, when the measurement value reaches a value preset for the home position, the rotation is stopped. Accordingly, the rotary floater 14 can be stopped at the home position with high accuracy.

The magnetic attraction force applied by the XY rotating electromagnet group 18 to the XY rotating attraction bodies 80 of the rotary floater 14 will be described in detail. Here, the description will be made by referring to one electromagnetic unit 86. As shown in FIG. 9, in the electromagnetic unit 86, a vertical magnetic circuit is formed by one yoke 88, two electromagnets 86a and 86b, two magnetic poles 82a and 82b, and one attraction body 80 corresponding thereto.

When a magnetic field 90 is generated, a magnetic attraction “fa” acts on the attraction body 80 as shown in the top view of FIG. 11. In this case, the direction of the magnetic attraction fa is applied in a direction slightly outward from a tangential direction of the rotary floater 14, rather than the tangential direction. Therefore, the magnetic attraction fa can be divided into a rotation torque “ft” as a force acting in the tangential direction of the rotary floater 14 and an outwardly directed force (diametrically acting force) “fr” applied in a radially outward direction of the rotary floater 14.

FIG. 7 is a graph showing changes in the respective forces. The vertical magnetic circuit is formed in accordance with the rotation angle as described above, so that each of the forces is represented as a function of the rotation angle “θ”. Here, the rotation angle θ indicates an angle formed by intermediate points in the circumferential directions of the electromagnetic unit 86 and the attraction body 80 in the cross section perpendicular to the rotation axis of the rotary floater 14. In FIG. 7, when the attraction body 80 is positioned at the center of the electromagnetic unit 86, the rotation angle θ becomes zero.

The rotation angle range in which a force applied by one XY rotating electromagnetic unit 86 is acted on the attraction body 80 is about ±30°. At this time, the attraction body 80 is moved as shown in FIGS. 10A to 10C.

In other words, as the attraction body 80 approaches from outside the electromagnetic unit 86 (FIG. 10A), the outwardly directed force fr is gradually increased, whereas the rotation torque ft is gradually decreased from the maximum value. When both are completely overlapped (FIG. 10B), the outwardly directed force fr becomes maximum, and the rotation torque ft becomes zero. If the rotation proceeds further (FIG. 10C), the outwardly directed force fr is gradually decreased, whereas the rotation torque ft is gradually increased in a reverse direction.

In the actual control process, the rotation torque ft is applied in a reverse direction and, at the same time, the magnetizing current of the XY rotating electromagnetic unit 86 is switched OFF. Therefore, the rotation torque is not applied in the reverse direction of the rotation direction. Specifically, as described above, the electromagnetic units 86 which are adjacent to each other in a circumferential direction form a pair. In total, six pairs are provided. The adjacent electromagnetic units 86 in each pair are controlled such that the magnetizing current thereof are alternately switched ON and OFF in accordance with the rotation of the rotary floater 14.

By properly controlling the magnetic attraction fa as described above, i.e., by properly controlling the magnetic current, it is possible to properly control the rotation torque ft and the outwardly directed force fr in each of the XY rotating electromagnetic units 86. At this time, in a single electromagnetic unit 86, it is not possible to individually control the rotation torque ft and the outwardly directed force fr. However, when the XY rotating control unit 94 combines rotation torques ft generated by the electromagnetic units 86, and also combines outwardly directed forces thereof, the forces acting in the X and Y directions and the rotation torque applied to the rotary floater 14 can be individually controlled. Accordingly, as described above, the rotary floater 14 can be smoothly rotated without misalignment in the center of rotation of the rotary floater 14.

In the processing apparatus for performing a predetermined process on the wafer W as a target object to be processed, the rotation torque and the diametrically acting force (outwardly directed force) can be generated simultaneously by applying a magnetic attraction from the XY rotating electromagnet group 18 to the XY rotating attraction bodies 80 provided at the rotary floater 14 in a state where the rotary floater 14 is floated by the floating electromagnet group 16. Accordingly, it is possible to suppress unnecessary external factors from being generated by controlling the diametrically (X and Y directions) acting force and the rotation torque of the rotary floater 14 by the same electromagnet. As a result, the particle free environment can be realized while obtaining the in-plane processing uniformity, and the structures and the control processes can be simplified.

Especially, since the rotation torque and the outwardly directed force are controlled by the magnetic attraction of the XY rotating electromagnet group 18 while floating the rotary floater 14 for supporting the target object W by the floating electromagnet group 16 without contact with the processing chamber 6, it is possible to suppress generation of external factors and achieve more stable floating rotation compared to the conventional apparatus in which the rotating electromagnet and the horizontal positioning electromagnet are individually provided.

As a result, the particle free environment can be realized while obtaining the in-plane processing uniformity. Further, it is possible to obtain the apparatus not only having an in-plane temperature uniformity but also ensuring a uniform film thickness and a high production yield can be accomplished.

The floating electromagnet group 16 applies a vertically upward acting magnetic attraction to the rotary floater 14, so that the rotary floater 14 is floated without having contact with the inner wall of the processing chamber 6. Therefore, the direction of the magnetic attraction and the direction of the gravity applied to the rotary floater 14 coincide with each other. Consequently, the horizontal misalignment can be prevented, and the stable control can be realized.

When heat treatment or the like is performed on the target object W, the temperature inside the processing chamber 6 is increased. In the case of providing a permanent magnet as described in U.S. Pat. No. 6,157,106, the permanent magnet is deteriorated by the effect of high-temperature heat, which increases the cost. However, in the present embodiment, such drawbacks can be solved by employing the combination of the electromagnet and the soft magnetic body.

Besides, in the present embodiment, the XY rotating attraction bodies 80 that are heavy in weight compared to aluminum are partially provided. Thus, the weight of the rotary floater 14 can be reduced compared to the conventional structure in which the magnetic attraction body of the rotary floater is provided along the entire circumferential direction as described in Japanese Patent Application Publication No. 2008-305863. Hence, the controllability can be accordingly improved.

(Explanation of Various Correction Functions)

Hereinafter, various correction functions executed during the operation of the processing apparatus will be explained.

(1) Correction of Characteristics of Attractive Force

As for the floating electromagnet group 16, the XY rotating electromagnet group 18 and the like, the attractive forces in various gaps between an electromagnet and an attraction body inevitably have different characteristics (variations) from designed characteristics due to manufacturing/assembly errors, magnetic flux leakage, changes in permeability and the like. For that reason, the characteristics are previously obtained, and the variations in the characteristics are canceled out by performing feedback control based on the corresponding characteristics during actual operation. Hence, the rotation control of the rotary floater 14 can be stably carried out.

(2) Correction of Magnetic Restoring Force in X and Y Directions

The rotary floater 14 is lifted upward by the floating electromagnet group 16, and the height thereof is controlled at a predetermined position. At this time, the rotary floater 14 tends to stay at the vertical position determined by the floating electromagnet group 16. If the horizontal position of the rotary floater 14 is controlled in this state, the balance is lost, and the restoring force acting in the reverse direction to that of the applied force is generated. This force is changed in accordance with the floating gap and the displacements in the X and Y directions. Accordingly, such characteristics are previously obtained, and the feedback-control is performed during an actual control process. As a consequence, the control can be performed stably in a wide range.

(3) Correction of Distortion of Rotary Floater

When the rotary floater 14 has a large diameter, distortion caused by a degree of a processing accuracy, fixed error or the like cannot be ignored for desired control accuracy. Meanwhile, the fabrication or assembly with high accuracy leads to remarkable increase in the processing cost or the maintenance cost. Therefore, there is used a method that ignores acceptable errors while avoiding instabilization or deterioration of the control accuracy within the error range.

Specifically, the actual displacements in the rotation angle, the X and Y positions and the floating height of the rotary floater 14 that is actually rotated in a floating state are measured, so that data including delays of a measurement system, an electric system and a control system are obtained. By calculating the distortion of the rotary floater 14 from this data and then repetitively providing feedback thereon, the actual distortion (the effect of the actual distortion) can be obtained without the measurement performed after unloading the rotary floater 14 to the outside of the apparatus. Further, by providing feedback on the distortion information to the displacement information during the actual operation, the control as good as the case when there is no distortion (effect of the distortion) can be realized as long as the distortion (the effect of the distortion) is constantly maintained.

More Specifically, in the case of a large rotary floater 14 for supporting a wafer having a diameter of, e.g., about 30 cm, a vertical distortion that hinders the horizontal rotation having no tilt may occur at the floating attraction body 66 formed of a ring-shaped magnetic steel plate which forms a part of the rotary floater 14. In this case, the distortion occurring during the rotation of the rotary floater 14 is previously stored as distortion data in the floating control unit 78, and the floating attraction body 66 where the distortion occurs is considered as the reference. The rotary floater 14 can be horizontally rotated, in spite of the distortion, by compensating the measurement value obtained by the vertical position sensor unit with remedy determined based on the distortion data during the actual operation.

In this case, however, the structures extending from the floating attraction body 66 to the supporting arm 62 via the supports 65, the rotary main body 58 and the supporting ring 60 are formed as one unit. Therefore, the distortion state of the floating attraction body 66 affects the supporting arm 62 for supporting the wafer W. Hence, the height of the supporting arm 62 needs to be previously adjusted to cancel out the distortion.

(4) Correction of Advance Angle

Due to the rotational speed or the response delay of the XY rotating electromagnet group 18 or the measurement system, the calculation value and the actual acting force are misaligned in angle. Thus, the angle is corrected in accordance with the rotational speed of the rotary floater 14. As a result, the stability in the X and Y directions and the rotation torque characteristics can be improved.

(5) Use of Both V-Shaped Cut-Out Portion and Encoder Unit

As described above, the encoder unit is effectively used for detecting a rotation angle. Meanwhile, a high-resolution encoder unit is required to perform high-accuracy angle positioning. However, the high-resolution encoder unit is costly and is difficult to apply due to the small gap between the code pattern and the detection sensor unit. Therefore, in the present embodiment, the position detection is generally performed by the encoder unit 96, and the V-shaped cut-out portion 102 is formed only at the specific location where the high-accuracy angle positioning is required (see FIG. 8). Moreover, the high-accuracy rotation angle can be obtained in an analog manner based on the relationship between the displacement of the cut-out portion 102 and the rotation angle.

The home position for loading and unloading the wafer W into and from the processing chamber 6 is considered as a location where the high-accuracy positioning is required. In this position, when a wafer transfer arm is moved into the processing chamber 6, it should not interfere with the supporting arm 62. Moreover, the annealed wafer W needs to be transferred to the wafer transfer arm while maintaining a predetermined orientation flat angle (notch angle).

As described with reference to FIG. 8, when a V-shaped cut-out portion having a depth of about 2.0 mm and a width of about ±3° (rotation angle) is formed at a part of the periphery of the rotary floater 14, the rotation angle is obtained from the depth of the V-shaped cut-out portion 102. The angle positioning accuracy can be realized in accordance with the depth measurement accuracy.

(6) Origin Position Detecting Method when θ Position is Uncertain

For example, after the maintenance or the assembly of the processing apparatus is completed, a rotation angle θ of the rotary floater 14 may be uncertain. In that case, an operational state of the rotary floater 14 is detected by setting a preset proper rotation angle θ, and a rotational speed thereof is specified in the following sequences.

When the θ position as the rotation angle is uncertain, a rotation torque is applied to the rotary floater 14 by assuming a proper 8 position. In this case, the rotation of the rotary floater 14 is divided into the following four types (cases) in accordance with the stop position:

(a) The rotary floater 14 is rotated in a CW (clockwise) direction;

(b) The rotary floater 14 is rotated in a CCW (counterclockwise) direction;

(c) The rotating direction of the rotary floater 14 is uncertain; and

(d) The rotary floater 14 is not rotated.

In the case of (c) and (d), the positional relationships between the XY rotating electromagnetic units 86 and the XY rotating attraction bodies 80 are actually the same. When the electromagnetic units 86 are arranged at an interval of about 30°, the attraction bodies 80 can be rotated by misaligning the magnetized electromagnetic units 86 by about 30°. In other positions, the state (a) or (b) is obtained. In other words, the attraction bodies 80 can be rotated by applying the rotation torque while assuming a proper 8 position.

Hence, the attraction bodies 80 can be rotated in either the CW direction or the CCW direction at any stop position. At this time, the rotation direction and the rotational speed can be read in accordance with the changes in the count value of the encoder unit 96. Since, however, the absolute value of the θ position is uncertain immediately after the rotation starts, it is not possible to determine ON/OFF switching timing of each pair of the electromagnetic units 86. Accordingly, if the magnetization to the electromagnetic units 86 is not switched, the rotation direction of the attraction bodies 80 that start to be rotated is changed, or the rotational speed thereof is decreased.

Therefore, if the electromagnetic units 86 misaligned by about 30° in the rotation direction is magnetized immediately after the rotation direction is changed or immediately after the rotational speed is decreased, the attraction bodies 80 can be rotated again in the rotation direction. By repeating this process, the origin mark 98 traverses the origin sensor unit 100. As a consequence, the encoder unit 96 is reset, and the accurate θ position (absolute value of θ position) can be obtained. Thereafter, the θ position can be controlled to the origin position by performing the origin positioning control.

(Examination of Diffusedly Reflective Surfaces 158 and 164)

Next, the diffusedly reflective surfaces 158 and 164 provided at the rotary floater 14 were examined. A description will be made on the result of the examination. Here, illuminance sensors were used as the vertical position sensor unit 75 and the horizontal position sensor unit 92, as described above. Therefore, when the mirror surface is used as the reflective surface of the target object for distance measurement, the direction of the reflective light is greatly changed by slight changes in the position. Further, the reflective light is greatly affected by small irregularities or processing traces (tool marks or the like) existing on the reflective surface. Especially, the diffusedly reflective surface 158 facing the horizontal position sensor unit 92 is formed as a cylindrical curved surface, so that the direction of the reflective light is greatly changed by slight changes in the position.

Accordingly, the diffusedly reflective surfaces 158 and 164 for diffusedly reflecting the reflective light substantially uniformly in all directions are provided as described above. Here, the optimal conditions for performing the blasting process in the case of forming the diffusedly reflective surfaces 158 and 164 were examined. In this examination test, a substrate having a flat surface made of aluminum was used as a test piece, and the blasting process was performed on the corresponding surface after the flat surface of the substrate was processed to minimize the processing traces. In this blasting process, alumina and glass as examples of ceramic were used as the blast material, and the size of the blast grain, i.e., # (grain size) was varied.

As described above, when the average surface roughness of the substrate before the blasting process is higher than the desired surface roughness thereof after the blasting process, the reflective light is directed in a fixed direction due to irregularities larger than the surface roughness after the blasting process, which is not preferable. Therefore, the average surface roughness of the substrate before the blasting process is set to be lower than the desired surface roughness thereof after the blasting process.

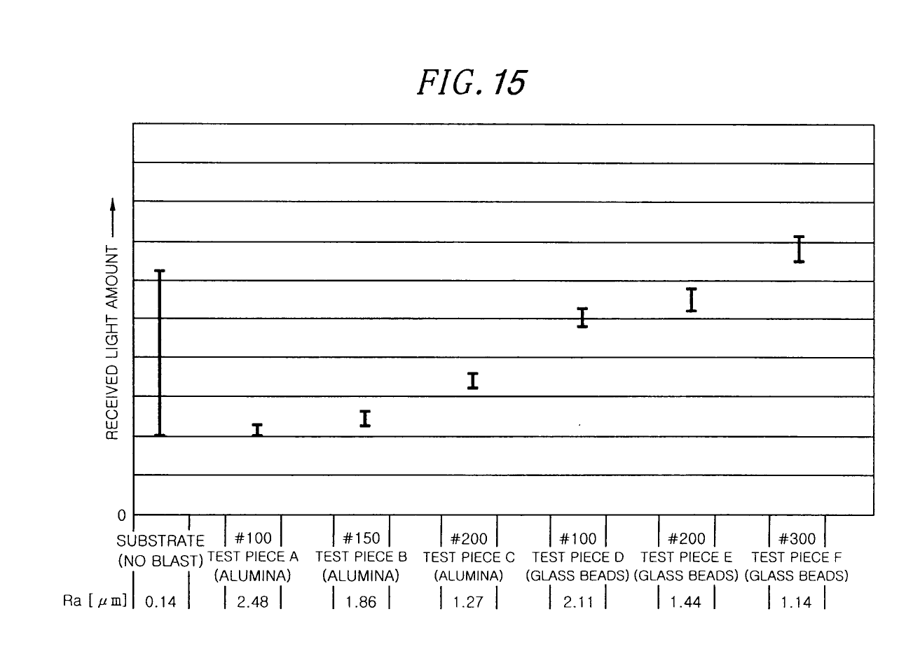

FIG. 15 is a graph showing relationships between the amounts of received light and test pieces A to F as substrates used when diffusedly reflective surfaces were examined. In the test pieces A to C, alumina was used as the blast material, and the grain sizes of the blast grains were variously set to #100, #150, and #200. In the test pieces D to F, glass beads were used as the blast material, and the grain sizes of the blast grains were variously set to #100, #200, and #300. In FIG. 15, average surface roughness “Ra” of each test piece after the blasting process is also shown.

The average surface roughness Ra of each substrate before the blasting process was set to about 0.14 μm. Each substrate was subjected to the blasting process in different manners. The amount of received light was measured by scanning the substrate. The average surface roughnesses of the test pieces A to F subjected to the blasting process were respectively about 2.48, 1.86, 1.27, 2.11, 1.44 and 1.14 μm.

First of all, the reflective light on the substrate which was not subjected to the blasting process and had an average surface roughness Ra of about 0.14 μm was measured. As a result, it has been found that the amount of received light was greatly changed (extended vertically) in accordance with the scanning of the substrate. This was because the reflective light had a directivity due to the effect of small processing traces or the like on the reflective surface having a small average surface roughness Ra close to the mirror state and, thus, the amount of received light was greatly changed in accordance with the scanning of the substrate. When the amount of received light is greatly changed, the measurement value related to the distance becomes unstable. Therefore, the illuminance sensor cannot be used as the sensor of the present invention.

On the other hand, in the test pieces A to F subjected to the blasting process, the changes in the amount of received light in accordance with the scanning of the substrate was considerably small, and the measurement value related to the distance became stable. Therefore, it has been found out that forming the diffusely reflecting surfaces by performing the blasting process is effective.

The amount of received light is larger in the case of using glass beads as the blast material than in the case of using alumina as the blast material, and the light can be easily detected by the light receiving device in the case of using glass beads as the blast material. Hence, it is preferable to use glass beads, instead of alumina, as the blast material.

When alumina is used as the blast material, the blast grains may have the grain sizes of #100, #150, and #200. However, it is preferable to use the grain size number of #200 that ensures a large amount of received light. When glass beads are used as the blast material, the blast grains may have the grain sizes of #100, #200, and #300. However, it is preferable to use the grain sizes #200 and #300 that ensure a large amount of received light.

### Second Embodiment

Hereinafter, a processing apparatus in accordance with a second embodiment of the present invention will be described. In the first embodiment described above, the floating electromagnet group 16 is provided in the casing 50 for rotary floater, i.e., the bottom portion of the processing chamber 6. However, the present invention is not limited thereto, and the floating electromagnet group 16 may be provided at a ceiling portion of the processing chamber 6 so that the entire height of the processing chamber 6 can be reduced.

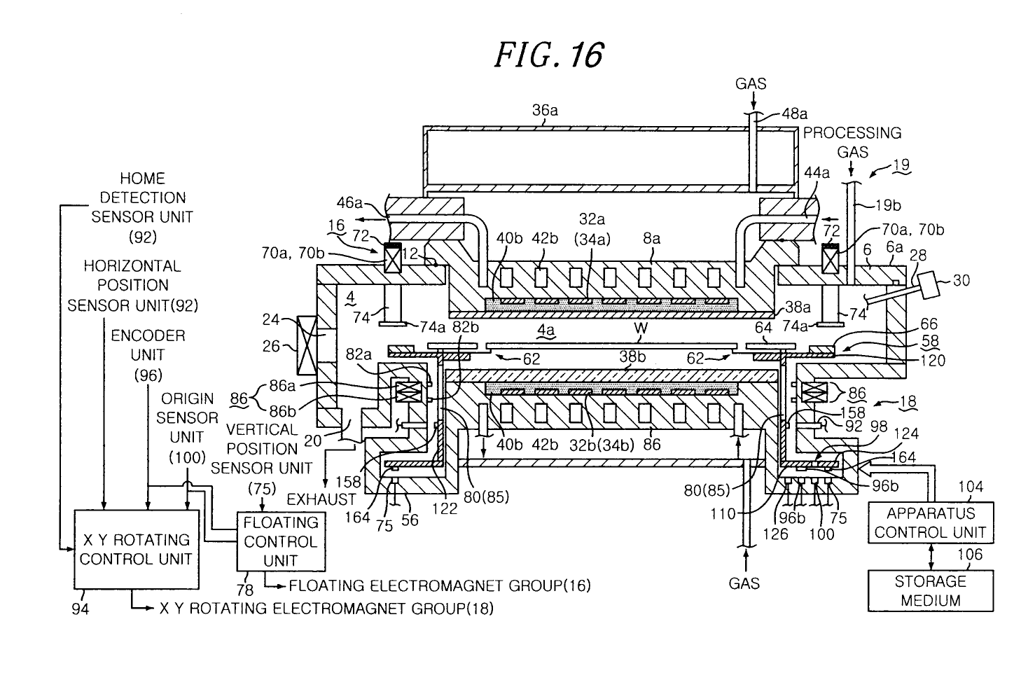

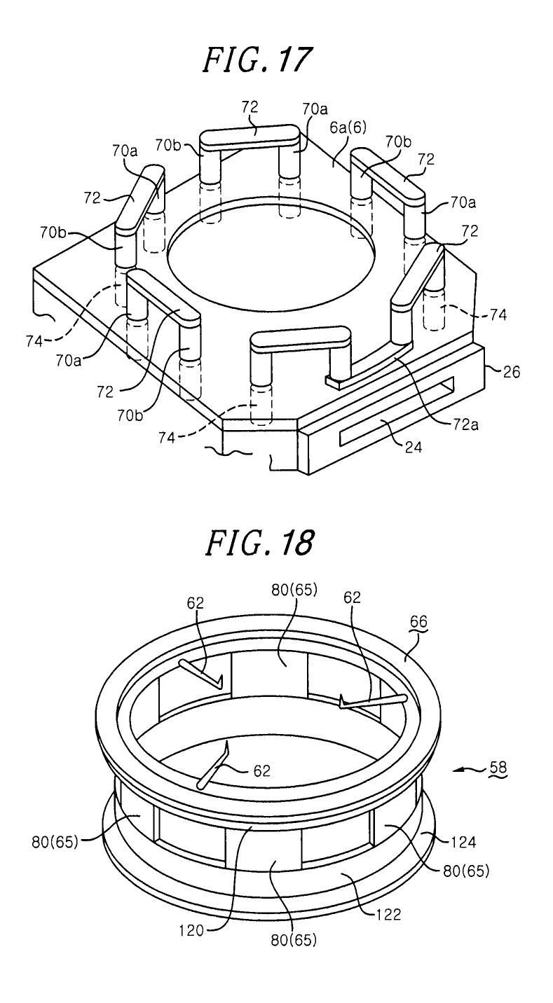

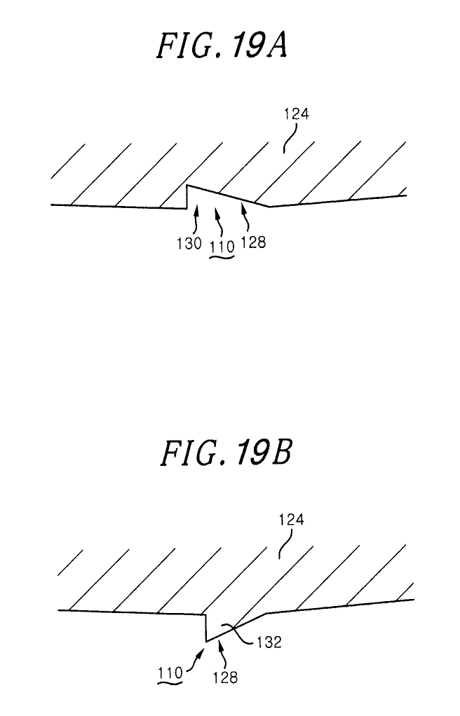

FIG. 16 is a full vertical cross sectional view showing a processing apparatus in accordance with the second embodiment of the present invention. FIG. 17 is a schematic perspective view showing a floating electromagnet group which is provided at a ceiling portion of a processing chamber. FIG. 18 is a schematic perspective view showing an example of a rotary floater. FIG. 19A is an enlarged cross sectional view showing an example of a home position adjustment portion. FIG. 19B is an enlarged cross sectional view showing another example of the home position adjustment portion. In FIGS. 16 to 19B, like reference numerals are used to designate like parts having the same configurations as those described in FIGS. 1 to 17, and the description thereof will be omitted.

As can be seen from FIGS. 16 and 17, the floating electromagnet group 16 is provided at a top wall 6a serving as the ceiling portion of the processing chamber 6. In this case, the top wall 6a is made of, e.g., a non-magnetic material such as aluminum, aluminum alloy or the like. The floating electromagnet group 16 is provided to face the peripheral portion of the rotary floater 14, the floating electromagnet group 16 being located thereabove. Specifically, as in the first embodiment, the floating electromagnet group 16 includes six floating electromagnetic units 68 spaced apart from each other at a regular interval along the circumferential direction of the top wall 6a.

The adjacent two of the six electromagnetic units 68 are paired with each other. In total, three pairs are disposed at the interval of about 120°. Each of the floating electromagnetic units 68 has two uprightly extending electromagnets 70a and 70b that are arranged in parallel, and the rear sides of the electromagnets 70a and 70b are connected to each other by one yoke 72 made of a ferromagnetic material. Since the three pairs of electromagnetic units 68 are arranged at the interval of about 120°, the inclination of the rotary floater 14 can be freely controlled, and the rotary floater 14 can be rotated by the XY rotating electromagnet group 18 and the like while maintaining the horizontal position thereof.

The attachment portions of the top wall 6a to which the electromagnets 70a and 70b are attached are formed in the shape of recesses, so that the attachment portions have a thin thickness of about 2 mm and are set to have small magnetic resistance. Column-shaped floating ferromagnetic members 74 extending downward are respectively provided at portions of the inner side (lower side) of the top wall 6a corresponding to the attachment portions to which the electromagnets 70a and 70b are attached. An enlarged portion 74a enlarged diametrically is attached to a leading end portion of each of the floating electromagnetic members 74, thereby increasing the magnetic attraction force.

With respect to the electromagnetic unit 68 adjacent to the loading/unloading port 24 for loading and unloading the wafer, in order to prevent interference with the wafer, there is provided an auxiliary yoke 72a that connects the lower end portions of the electromagnets 70a and 70b of the very electromagnetic unit instead of the cylindrical ferromagnetic member 74 (see FIG. 17). Accordingly, the magnetic circuit is prevented from being cut into pieces at the portion corresponding to the loading/unloading port 24.

In this manner, the magnetic circuit is formed by the yokes 72 and 72a, the two electromagnets 70a and 70b, the floating ferromagnetic members 74, and a floating attraction body 66 to be described later. The entire part of the rotary floater 14 can be floated (non-contact state) by the magnetic attraction acting on the floating attraction body 66.

Meanwhile, as shown in FIGS. 16 and 18, the rotary floater 14 installed in the processing chamber 6 has a ring-shaped upper rotary main body 120 and a lower rotary main body 122, which are made of a non-magnetic material, e.g., aluminum, aluminum alloy or the like, and are connected by the XY rotating attraction body 80 serving as the column 65.

As in the first embodiment, the XY rotating attraction bodies 80 are arranged at the regular interval along the circumferential direction of the rotary floater 14. As shown in FIG. 18, each of the XY rotating attraction bodies 80 is formed as a substantially rectangular plate along the circumferential direction of the upper rotary main body 120. In this embodiment, six XY rotating attraction bodies are provided. The XY rotating attraction bodies 80 may be made of a hard magnetic material or a soft magnetic material. In this embodiment, a soft magnetic material e.g., SS400, is used.

As in the case of the first embodiment, the length (width) of each of the XY rotating attraction bodies 80 in the rotation direction is set to be equal to the gap between the adjacent attraction bodies 80. The vertical length of each of the attraction bodies 80 is set to a length corresponding to a pair of magnetic poles 82a and 82b. As for the size of each of the attraction bodies 80, when the upper rotary main body 120 has a diameter of, e.g., about 600 mm, each of the attraction bodies 80 has vertical and horizontal dimensions of, e.g., about 50 mm×160 mm.

The XY rotating electromagnet group 18 is provided at the outer side of the attraction bodies 80. The upper portion of the upper rotary main body 120 is bent outward in the horizontal direction, and the ring-shaped floating attraction body 66 formed of, e.g., an electromagnetic steel plate, is attached and fixed thereon. In this case, the cylindrical floating ferromagnetic members 74 are positioned immediately above the floating attraction body 66 with a predetermined gap therebetween. Accordingly, as described above, the entire part of the rotary floater 14 is floated by the magnetic force generated between the floating ferromagnetic members 74 and the floating attraction body 66.

A lower portion of the lower rotary main body 122 is horizontally bent outward to form a bent portion 124. The bent portion 124 is provided with the code pattern 96a of the encoder unit 96, the origin mark 98, and the home position adjustment portion 110. The horizontal position sensor unit 75, the encoder sensor unit 96b, the origin sensor unit 100 and the home detection sensor unit 126 for detecting the home position adjustment portion 110 are provided at the ring-shaped horizontal flange portion 56 formed at the bottom portion of the processing chamber which faces the bent portion 124. The output of the home detection sensor unit 126 is inputted to the XY rotating control unit 94.

Unlike the first embodiment in which three home position adjustment portions 110 are provided, only one home position adjustment portion 110 is provided in the second embodiment. As shown in FIG. 19A, for example, the home position adjustment portion 110 of the present embodiment has a single measurement surface 128 inclined upward from the rotation direction of the rotary floater 14. This measurement surface 128 is formed by cutting the surface of the bent portion 124 to form a cut-out portion 130 having a triangular cross section.

Further, as shown in FIG. 19B, the measurement surface 128 may be formed to be inclined downward from the rotation direction by providing, instead of the cut-out portion 130, a protrusion 132 having a triangular cross section which is symmetrical to the triangular cut-out portion 130. As in the first embodiment, the rotary floater 14 of the present embodiment has the diffusely reflecting surfaces 158 and 164 that are respectively opposite to the horizontal position sensor unit 92 and the vertical position sensor unit 75.

The second embodiment can also provide the same operational effects as those of the first embodiment. In the second embodiment, the floating electromagnet group 16 is provided at an empty region above the ceiling portion of the processing chamber 6, so that the entire height of the processing apparatus can be reduced, which leads to scaling down of the processing apparatus. Further, in the second embodiment, the home position adjustment portion 110 described with reference to FIG. 6 may be employed.

The present invention can be variously modified without being limited to the above embodiments. For example, the above embodiments have described the case where the heating sources 32a and 32b having LEDs as processing units are provided at opposite sides of the wafer as an object to be processed. However, the heating sources may be provided at one side of the wafer. Moreover, although the above embodiments have described the case where the LEDs are used as light emitting devices, it is also possible to other light emitting devices such as semiconductor laser and the like. Further, the above embodiments have described the case of performing annealing as an example. However, the present invention can be applied to the case of performing other processes such as oxidation, film formation, diffusion and the like without being limited thereto. In addition, the temperature sensor 28 may be extended through the bottom portion of the processing chamber, instead of the side portion of the processing chamber 6.

In the above example, a semiconductor wafer is used as an example of a target object to be processed. This semiconductor wafer includes a silicon substrate or a compound semiconductor substrate such as GaAs, SiC, GaN or the like. Further, the present invention can be applied to a glass substrate for a liquid crystal display, a ceramic substrate or the like without being limited to the above substrates.

1. A processing apparatus for performing a process on a target object to be processed, comprising:
an evacuable processing chamber;
a rotary floater disposed within the processing chamber to support the target object on an upper end side thereof, the rotary floater being made of a non-magnetic material;
a plurality of XY rotating attraction bodies provided in the rotary floater at an interval in the circumferential direction thereof, the XY rotating attraction bodies being made of a magnetic material;
a ring-like floating attraction body provided in the rotary floater to extend in the circumferential direction thereof, the floating attraction body being made of a magnetic material;
a floating electromagnet group provided outside the processing chamber to float the rotary floater while adjusting an inclination of the rotary floater by applying a vertically upward acting magnetic attraction to the floating attraction body;
an XY rotating electromagnet group provided outside the processing chamber to rotate the rotary floater while adjusting a horizontal position of the floating rotary floater by applying a magnetic attraction to the XY rotating attraction bodies;
a gas supply unit for supplying a required gas into the processing chamber;
a processing mechanism for performing a process on the target object; and
an apparatus control unit for controlling an entire operation of the processing apparatus.

2. The processing apparatus of claim 1, further comprising:
a vertical position sensor unit for detecting vertical position information of the rotary floater; and
a floating control unit for supplying a control current to the floating electromagnet group to control a magnetic attraction based on an output of the vertical position sensor unit.

3. The processing apparatus of claim 1, further comprising:
a horizontal position sensor unit for detecting horizontal position information of the rotary floater;
an encoder unit for detecting a rotation angle of the rotary floater; and
an XY rotating control unit for controlling a rotation torque and a diametrical force acting on the rotary floater by supplying a control current for controlling a magnetic attraction of the XY rotating electromagnet group based on an output of the horizontal position sensor unit and an output of the encoder unit.

4. The processing apparatus of claim 3, wherein the rotary floater is provided with a home position adjustment portion having a measurement surface having an angle with respect to a rotation direction of the rotary floater, and
a home detection sensor unit for detecting the home position adjustment portion is provided in the processing chamber.

5. The processing apparatus of claim 4, wherein the home position adjustment portion has a pair of the measurement surfaces forming an angle, and
a straight line extending in a diametrical direction of the rotating float body and passing through the contact point between the pair of measurement surfaces is a bisector of the angle formed by the measurement surfaces.

6. The processing apparatus of claim 5, wherein the pair of measurement surfaces is formed as a V-shaped cut-out portion at a position corresponding to the horizontal position sensor unit, and
the pair of the measurement surfaces forming the cut-out portion is provided in plural at an interval along the circumferential direction of the rotary floater.

7. The processing apparatus of claim 6, wherein the horizontal position sensor unit also serves as the home detection sensor unit, and
the XY rotating control unit is configured to stop the rotary floater at a home position by detecting a depth of the cut-out portion in the case of stopping the rotary floater.

8. The processing apparatus of claim 4, wherein the XY rotating control unit is configured to stop the rotary floater at a home position by detecting a position of the measurement surface in the diametrical direction of the rotary floater based on an output of the home detection sensor unit in the case of stopping the rotary floater.

9. The processing apparatus of claim 1, wherein the rotary floater is provided with an origin mark indicating the origin, and
the processing chamber is provided with an origin sensor unit for detecting the origin mark.

10. The processing apparatus of claim 1, wherein the floating electromagnet group includes plural pairs of floating electromagnetic units, each pair being formed of two electromagnets having rear surfaces connected to each other by a yoke, and
the plural pairs of floating electromagnetic units are arranged at an interval along the circumferential direction of the processing chamber.

11. The processing apparatus of claim 1, wherein the XY rotating electromagnet group includes plural pairs of XY rotating electromagnetic units, each pair being formed of two electromagnets having rear surfaces connected to each other by a yoke,
wherein the plural pairs of XY rotating electromagnetic units are arranged at an interval along the circumferential direction of the processing chamber.

12. The processing apparatus of claim 11, wherein the two electromagnets of each pair of the XY rotating electromagnetic units are arranged at different levels in a height direction of the processing chamber, and
plural pairs of magnetic poles made of a ferromagnetic material are provided in the processing chamber while being spaced from each other at an interval along the circumferential direction of the processing chamber, each pair of the magnetic pole being arranged to correspond to the two electromagnets of each pair of the electromagnetic units.

13. The processing apparatus of claim 1, wherein the floating electromagnet group is provided at a bottom portion of the processing chamber.

14. The processing apparatus of claim 1, wherein the floating electromagnet group is provided at a ceiling portion of the processing chamber.

15. The processing apparatus of claim 2, wherein a diffusely reflecting surface for diffusedly reflecting a measurement light is formed on a surface of the rotary floater which faces the vertical position sensor unit.

16. The processing apparatus of claim 3, wherein a diffusely reflecting surface for diffusedly reflecting a measurement light is formed on the surface of the rotary floater which faces the horizontal position sensor unit.

17. The processing apparatus of claim 15, wherein the diffusely reflecting surface is formed by a blasting process.

18. The processing apparatus of claim 17, wherein a size number of a blast grain in the blasting process ranges from #100 (grain size number 100) to #300 (grain size number 300).

19. The processing apparatus of claim 17, wherein the blast grain is made of a material selected from a group consisting of glass, ceramic, and dry ice.

20. The processing apparatus of claim 17, wherein an average surface roughness of a blast target surface before the blasting process is set to be smaller than a desired average surface roughness after the blasting process.

21. The processing apparatus of claim 17, wherein an alumite film is formed on the diffusedly reflective surface after the blasting process.

22. The processing apparatus of claim 15, wherein the diffusely reflecting surface is formed by an etching process.

23. The processing apparatus of claim 15, wherein the diffusely reflecting surface is formed by a coating process.

24. A method for operating the processing apparatus of claim 1, the method comprising:
floating the rotary floater while controlling an inclination thereof by applying a magnetic attraction to the floating attraction body by the floating electromagnet group; and
rotating the rotary floater while controlling a horizontal position thereof by applying a magnetic attraction to the XY rotating attraction bodies by the XY rotating electromagnet group.

25. The method of claim 24, further comprising:
controlling the floating control unit to control the floating electromagnet group and the XY rotating control unit to control the electromagnet group during processing of the target object based on variation data on variations in characteristics,
wherein the variation data on variations in characteristics are obtained by previously rotating the rotary floater by the floating control unit and the XY rotating control unit.

26. The method of claim 24, further comprising:
controlling the floating control unit to control the floating electromagnet group and the XY rotating control unit to control the XY rotating electromagnet group during processing of the target object based on distortion data on distortion of the rotary floater,
wherein the distortion data on distortion of the rotary floater are obtained by previously rotating the rotary floater by the floating control unit and the XY rotating control unit.

27. The method of claim 24, wherein the XY rotating control unit stops the rotary floater at a home position based on an output of an encoder unit for detecting a rotation angle of the rotary floater and an output of the home detection sensor unit for detecting a home position adjustment portion having measurement surfaces formed at the rotary floater, in the case of stopping the rotary floater.

28. The method of claim 27, wherein the home position adjustment portion is formed by arranging a plurality of V-shaped cut-out portions along a circumferential direction of the rotary floater, each of the cut-out portions being formed as a pair of measurement surfaces,
and the home detection sensor unit also serves as a horizontal position sensor unit for detecting a horizontal position of the rotary floater.

29. The method of claim 24, further comprising:
supplying, when the rotary floater starts to rotate at an uncertain position, a control current for rotating the rotary floater in one direction to the XY rotating electromagnetic units while assuming that the rotary floater is stopped at a preset home position;
supplying, when the rotary floater stops its rotation, a control current, for magnetizing the XY rotating electromagnetic units by misaligning the XY rotating electromagnetic units of the XY rotating electromagnet group by an angle, to the XY rotating electromagnet group;
supplying, when the rotary floater is rotated at a decreasing speed, a control current, for rotating the rotary floater in a reverse direction, to the XY rotating electromagnet group; and
resetting the encoder unit by detecting an origin position when an origin mark of the rotary floater passes through an origin sensor unit.
